(19) United States
(12) Patent Application Publication
(10) Pub. No.: US 2020/0343392 A1
(43) Pub. Date: Oct. 29, 2020

(54) VARISTOR-BASED PHOTODETECTOR AND IMAGE SENSOR COMPRISING SAME

(71) Applicant: KONKUK UNIVERSITY INDUSTRIAL COOPERATION CORP, Seoul (KR)

(72) Inventors: Hyun Jong Chung, Hwaseong-Si, Gyeonggi-do (KR); Jun Ho Lee, Jangan-Gu, Suwon-si, Gyeonggi-do (KR)

(73) Assignee: KONKUK UNIVERSITY INDUSTRIAL COOPERATION CORP, Seoul (KR)

(21) Appl. No.: 16/755,827

(22) PCT Filed: Oct. 12, 2018
(86) PCT No.: PCT/KR2018/012029

§ 371 Date: Apr. 13, 2020

(30) Foreign Application Priority Data
Oct. 13, 2017 (KR) 10-2017-0133362

(51) Int. Cl. H01L 31/032; H01L 27/146; H01L 29/16; H01L 29/423; H01L 31/112

(52) U.S. Cl. CPC H01L 31/0324; H01L 27/14603; H01L 27/14614; H01L 29/42364; H01L 31/112; H01L 29/1606

(57) ABSTRACT

A barristor-based photodetector is disclosed. The photodetector according to an embodiment comprises: a substrate; a gate electrode which is laminated on the substrate; a first electrode and a second electrode which are laminated on the substrate and spaced apart from the gate electrode; a graphene layer which is formed between the substrate and the second electrode and extends toward the first electrode; and a gate insulating layer which is formed between the gate electrode and the graphene layer.

### TECHNICAL FIELD

The following example embodiments relate to a barristor-based photoconductor and an image sensor including the same.

### BACKGROUND ART

A photodetector based on an existing semiconductor determines minimum energy of absorbed light based on a size of a band gap of a semiconductor. Here, the photodetector detects (or absorbs) light corresponding to minimum energy of the semiconductor or light greater than the light.

In a photodetector using a Schottky diode, minimum energy of absorbed light is determined based on a height of a Schottky barrier. Here, energy of light absorbed by the photodetector is determined by a specific semiconductor or a specific combination of semiconductor metals, and it is impossible to change the energy after fabrication.

### DISCLOSURE OF INVENTION

### Technical Subject

Example embodiments may provide technology of adjusting a wavelength band of minimum energy of absorbed light by changing gate voltage for a gate electrode, to specify and vary a wavelength band of energy of the absorbed light and detect and measure energy of light and an intensity of the light.

Also, example embodiments may provide technology of adjusting a wavelength band of minimum energy of absorbed light to be further widened, using a two-dimensional (2D) semiconductor having a characteristic in which an energy band gap varies depending on a thickness, and of more widely varying a wavelength band of energy of the absorbed light.

Also, example embodiments may provide technology of utilizing a photodetector for detecting and measuring energy of light and an intensity of the light in a sensor that measures various wavelength bands.

### Technical Solution

According to an aspect, there is provided a photoconductor including a substrate, a gate electrode laminated on the substrate, a first electrode and a second electrode laminated on the substrate and spaced apart from the gate electrode, a graphene layer formed between the substrate and the second electrode and extending toward the first electrode, and a gate insulating layer formed between the gate electrode and the graphene layer.

The substrate may be implemented as at least one of a semiconductor substrate and a nonconductor substrate.

The substrate may be one of silicon, germanium, silicon-germanium, a Group III-V semiconductor, a Group II-VI semiconductor, a semiconducting CNT, MoS₂, IZO, and GIZO.

The nonconductor substrate may include at least one of SiO₂, and Si.

The photoconductor may further include a two-dimensional (2D) semiconductor formed to contact the first electrode and the graphene layer.

The 2D semiconductor may include a first layer formed with a first thickness, and a second layer formed with a second thickness.

The first layer may form a first junction with the first electrode, and the second layer may form a second junction with the graphene layer.

The first thickness may be either the same as or different from the second thickness.

The first junction may be one of a Schottky junction and an ohmic junction.

The second junction may be one of the Schottky junction and the ohmic junction.

The 2D semiconductor may be at least one of tungsten disulfide, transition metal dichalcogenides (TMDs), and black phosphorus.

The TMDs may include at least one of WSe₂, WTe₂, MoS₂, MoSe₂, and MoTe₂.

The photoconductor may further include an insulating layer formed between the graphene layer and the first electrode.

The gate electrode may directly contact the substrate and may be formed between the substrate and the gate insulating layer.

According to another aspect, there is provided an image sensor including a pixel array including a plurality of color pixels and an infrared ray (IR) pixel including a photoconductor based on a barristor device to detect light in an IR band.

The photoconductor may include a substrate, a gate electrode laminated on the substrate, a first electrode and a second electrode laminated on the substrate and spaced apart from the gate electrode, a graphene layer formed between the substrate and the second electrode and extending toward the first electrode, and a gate insulating layer formed between the gate electrode and the graphene layer.

The substrate may be implemented as at least one of a semiconductor substrate and a nonconductor substrate.

The substrate may be one of silicon, germanium, silicon-germanium, a Group III-V semiconductor, a Group I-VI semiconductor, a semiconducting CNT, MoS₂, IZO, and GIZO.

The nonconductor substrate may include at least one of SiO₂, and Si.

The image sensor may further include a two-dimensional (2D) semiconductor formed to contact the first electrode and the graphene layer.

The 2D semiconductor may include a first layer formed with a first thickness, and a second layer formed with a second thickness.

The first layer may form a first junction with the first electrode, and the second layer may form a second junction with the graphene layer.

The first thickness may be either the same as or different from the second thickness.

The first junction may be one of a Schottky junction and an ohmic junction.

The second junction may be one of the Schottky junction and the ohmic junction.

The 2D semiconductor may be at least one of tungsten disulfide, transition metal dichalcogenides (TMDs), and black phosphorus.

The TMDs may include at least one of WSe₂, WTe₂, MoS₂, MoSe₂, and MoTe₂.

The image sensor may further include an insulating layer formed between the graphene layer and the first electrode.

The gate electrode may directly contact the substrate and may be formed between the substrate and the gate insulating layer.

### BRIEF DESCRIPTION OF DRAWINGS

FIG. 1 schematically illustrates a structure of a barristor device to describe a concept of a photodetector according to an example embodiment.

FIGS. 2A and 2B illustrate an example of an energy band diagram of the barristor device of FIG. 1.

FIGS. 3A and 3B illustrate another example of the energy band diagram of the barristor device of FIG. 1.

FIG. 4 illustrates an example of a barristor device-based photodetector.

FIG. 5 illustrates another example of a barristor device-based photodetector.

FIG. 6 illustrates still another example of a barristor device-based photodetector.

FIG. 7 illustrates an example of a two-dimensional (2D) semiconductor of a photodetector shown in FIG. 6.

FIG. B illustrates yet another example of a barristor device-based photodetector.

FIG. 9 illustrates an example of an image sensor including a barristor device-based photodetector.

FIG. 10 illustrates an example of a pixel array of FIG. 9.

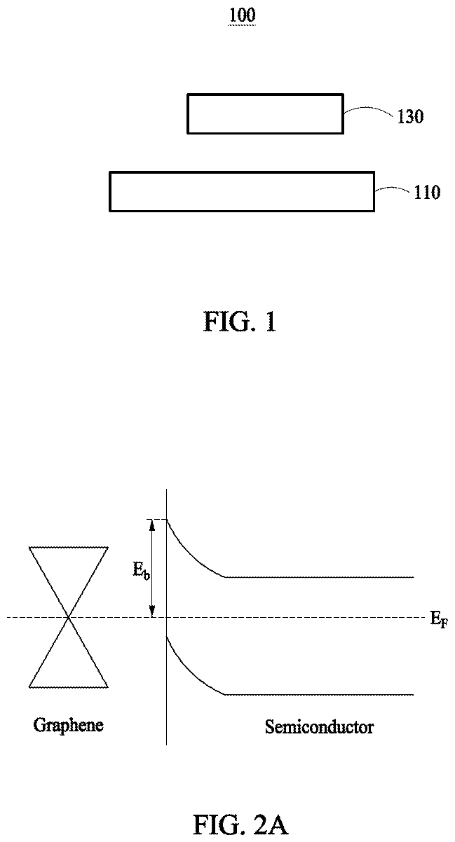

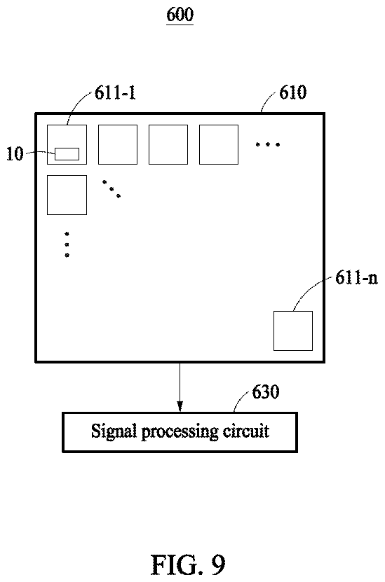

FIG. 1I illustrates another example of the pixel array of FIG. 9.

### BEST MODE FOR CARRYING OUT THE INVENTION

Specific structural or functional descriptions of example embodiments according to the concept of the present invention are merely intended for the purpose of describing example embodiments and the example embodiments may be implemented in various forms and should not be construed as being limited to those described in the present disclosure.

Various modifications may be made to the example embodiments, some of which will be illustrated in detail in the drawings and detailed description. However, it should be understood that these example embodiments are not construed as limited to the illustrated forms and include all changes, equivalents or alternatives within the idea and the technical scope of the present invention.

Although terms of “first” or “second” are used to explain various components, the components are not limited to the terms. These terms are used only to distinguish one component from another component. For example, a “first” component may be referred to as a “second” component, or similarly, the “second” component may be referred to as the “first” component within the scope of the right according to the concept of the present invention.

It should be noted that if it is described in the specification that one component is “connected,” or “coupled” to another component, a third component may be “connected,” and “coupled” between the first and second components, although the first component may be directly connected, coupled or joined to the second component. In addition, it should be noted that if it is described in the specification that one component is “directly connected” or “directly coupled” to another component, a third component may not be present therebetween. Likewise, expressions, for example, “between” and “immediately between” and “adjacent to” and “immediately adjacent to” may also be construed as described in the foregoing.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “may include” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be described in detail with reference to the accompanying drawings. The scope of the right, however, should not be construed as limited to the example embodiments set forth herein. Regarding the reference numerals assigned to the elements in the drawings, it should be noted that the same elements will be designated by the same reference numerals.

FIG. 1 schematically illustrates a structure of a barristor device to describe a concept of a photodetector according to an example embodiment.

Referring to FIG. 1, a barristor device 100 includes a substrate 110 and a graphene layer 130.

The barristor device 100 may further include a plurality of electrodes, for example, a gate electrode (not shown), a source electrode (not shown) and a drain electrode (not shown). The plurality of electrodes may be laminated above or below the substrate 100 and/or the graphene layer 130 such that voltage may be applied.

The substrate 110 may be implemented as a semiconductor substrate or a nonconductor substrate. When the substrate 110 is implemented as a semiconductor substrate, the semiconductor substrate may be doped with either n-type impurities or p-type impurities. For example, the semiconductor substrate may be formed of silicon, germanium, silicon-germanium, a Group III-V semiconductor, a Group II-VI semiconductor, a semiconducting CNT, a two-dimensional (2D) semiconductor (for example. MoS₂, and WS₂) including transition metal dichalcogenides. IZO, GIZO, and the like.

The graphene layer 130 may be formed by transferring graphene manufactured by chemical vapor deposition (CVD) and patterning the transferred graphene. For example, the graphene layer 130 may be implemented by a single layer through four layers of graphene. The graphene layer 130 may be a path through which carriers are moved.

The graphene layer 130 may be directly grown and formed on the substrate 110.

The graphene layer 130, for example, a work function of graphene, may vary depending on gate voltage applied to a gate electrode due to inherent properties of graphene. Also, an energy band of the substrate 110 may be affected by the gate voltage.

A height (or a size) of an energy barrier (or a junction) between the graphene layer 130 and the substrate 110 may be determined based on a difference between the work function of the graphene based on the gate voltage and an energy band (or a conduction band or a valence band) of the substrate 110.

In other words, the barristor device 100 may control the height of the energy barrier between the graphene layer 130 and the substrate 110 based on the gate voltage. Accordingly, a photodetector based on the barristor device 100 may absorb energy of various lights by controlling the height of the energy barrier between the graphene layer 130 and the substrate 110 based on the gate voltage. Also, in a state in which energy of light is fixed, it is impossible for the photodetector to absorb light when the height of the energy barrier is greater than the energy of the light, however, the photodetector may absorb light when the height of the energy barrier is less than or equal to the energy of the light.

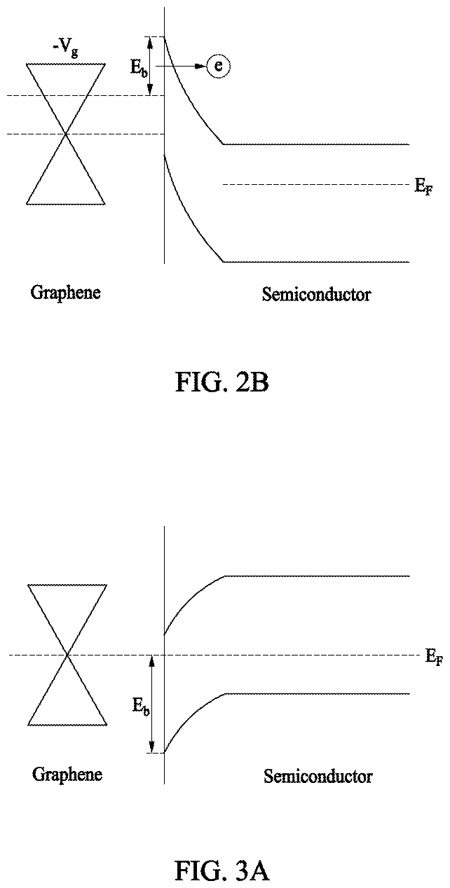

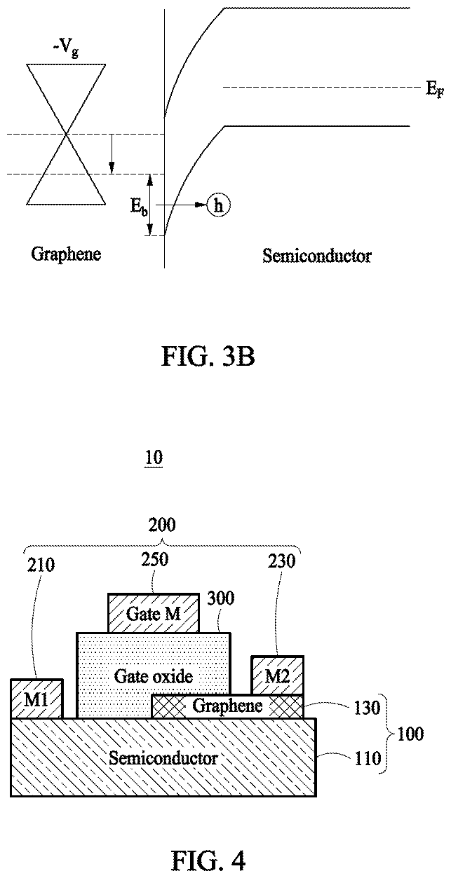

Controlling of the energy barrier of the barristor device 100 will be described based on energy band diagrams of the barristor device 100 with reference to FIGS. 2A through 3B.

FIGS. 2A and 2B illustrate an example of an energy band diagram of the barristor device of FIG. 1.

FIGS. 2A and 2B illustrate energy band diagrams of the barristor device 100 when the substrate 110 is a substrate of a semiconductor doped with n-type impurities, or a semiconductor in which an energy difference between a Dirac point of the graphene and a conduction band is less than an energy difference between the Dirac point and a valence band.

Referring to FIG. 2A, in a state in which voltage is not applied to the plurality of electrodes, an energy band structure of the barristor device 100 may be formed corresponding to the energy band of the substrate 110 and the work function of the graphene. Here, a carrier of the barristor device 100 may become an electron and a movement of the carrier may be limited by an energy barrier E_{b} between the graphene layer 130 and the substrate 110. E_{F} refers to a Fermi energy level of the graphene layer 130.

Referring to FIG. 2B, in a state in which positive voltage is applied to the drain electrode, reverse bias voltage is applied between a source (or the source electrode) and a drain (or the drain electrode) and the energy barrier E_{b} increases. In other words, the energy barrier E_{b} is still large.

Here, when arbitrary plus voltage is applied to the gate electrode, the energy barrier E_{b} of the substrate 110 decreases as the Fermi energy level E_{F} of the graphene layer 130 moves upward as indicated by an arrow. Accordingly, the carrier may be easily transferred from the graphene layer 130 to the substrate 110.

FIGS. 3A and 3B illustrate another example of the energy band diagram of the barristor device of FIG. 1.

FIGS. 3A and 3B illustrate energy band diagrams of the barristor device 100 when the substrate 110 is a substrate of a semiconductor doped with p-type impurities, or a semiconductor in which an energy difference between a Dirac point of the graphene and a valence band is less than an energy difference between the Dirac point and a conduction band.

Referring to FIG. 3A, in a state in which voltage is not applied to the plurality of electrodes, an energy band structure of the barristor device 100 may be formed corresponding to the energy band of the substrate 110 and the work function of the graphene. Here, a carrier of the barristor device 100 may become a hole and a movement of the carrier may be limited by an energy barrier E_{b} between the graphene layer 130 and the substrate 110. E_{F} refers to a Fermi energy level of the graphene layer 130.

Referring to FIG. 3B, in a state in which negative voltage is applied to the drain electrode, reverse bias voltage is applied between a source (or the source electrode) and a drain (or the drain electrode) and the energy barrier E_{b} is still large.

Here, when arbitrary minus voltage is applied to the gate electrode, the energy barrier E_{b} of the substrate 110 may decrease as the Fermi energy level E_{F} of the graphene layer 130 moves downward as indicated by an arrow. Accordingly, the carrier may be easily transferred from the graphene layer 130 to the substrate 110.

Since the energy barrier E_{b} of the substrate 110 is adjusted based on a magnitude of the gate voltage as described above with reference to FIGS. 2A through 3B, an energy barrier E_{b} of the barristor device 100 may also be adjusted. For example, the energy barrier E_{b} of the barristor device 100 may adjust a barrier height of about 0.6 eV.

For example, the energy barrier E_{b} of the barristor device 100 may adjust a barrier height of about 0.6 eV. The energy barrier E_{b} of the barristor device 100 may a height of a Schottky barrier based on the magnitude of the gate voltage. The height of the Schottky barrier may occur between the substrate 110 and the graphene layer 130.

Hereinafter, a barristor device-based photodetector 10 shown in FIGS. 4 through 8 will be described.

FIG. 4 illustrates an example of a barristor device-based photodetector.

Referring to FIG. 4, a photodetector 10 includes a substrate 110, a graphene layer 130, a plural electrodes 200, and a gate insulating layer 300. The electrodes 200 may include a first electrode 210, a second electrode 230, and a gate electrode 250.

The substrate 110 may be implemented as a semiconductor substrate. For example, the semiconductor substrate may include one of silicon, germanium, silicon-germanium, a Group I-V semiconductor, a Group II-VI semiconductor, a semiconducting CNT, MoS2, IZO, and GIZO.

On the substrate 110, the graphene layer 130, the electrodes 200, and the gate insulating layer 300 may be laminated. For example, the graphene layer 130, the first electrode 210, and the gate insulating layer 300 may be laminated on the substrate 110 to be in direct contact with the substrate 110. The second electrode 230 and the gate electrode 250 may be laminated without contacting the substrate 110.

The graphene layer 130 may be formed between the substrate 110 and the second electrode 230 and may extend toward the first electrode 210. For example, the graphene layer 130 may directly contact the substrate 110, the second electrode 230 and the gate insulating layer 300, and may extend from the second electrode 230 toward the first electrode 210. The graphene layer 130 may be spaced apart from the first electrode 210 and the gate electrode 250 and disposed not to contact the first electrode 210 and the gate electrode 250.

The first electrode 210 and the second electrode 230 may be laminated on and above the substrate 110 and spaced apart from the gate electrode 250.

For example, the first electrode 210 may be laminated on the substrate 110 to be in direct contact with the substrate 110. The first electrode 210 may be spaced apart from the graphene layer 130, the second electrode 230, the gate electrode 250 and the gate insulating layer 300, and disposed not to contact the graphene layer 130, the second electrode 230, the gate electrode 250 and the gate insulating layer 300.

The second electrode 230 may be laminated on the graphene layer 130 to be in direct contact with the graphene layer 130. Here, the graphene layer 130 may be laminated on the substrate 110 to be in direct contact with the substrate 110. The second electrode 230 may be spaced apart from the substrate 110, the first electrode 210, the gate electrode 250 and the gate insulating layer 300 and disposed not to contact the substrate 110, the first electrode 210, the gate electrode 250 and the gate insulating layer 300.

The gate electrode 250 may be laminated above the substrate 110 and disposed not to contact the substrate 110. For example, the gate electrode 250 may be laminated on the gate insulating layer 300 to be in direct contact with the gate insulating layer 300. Here, the gate insulating layer 300 may be laminated on the substrate 110 to be in direct contact with the substrate 110. The gate electrode 250 may be spaced apart from the substrate 110, the graphene layer 130, the first electrode 210 and the second electrode 230, and disposed not to contact the substrate 110, the graphene layer 130, the first electrode 210 and the second electrode 230.

The gate insulating layer 300 may be formed between the gate electrode 250 and the graphene layer 130. For example, the gate insulating layer 300 may directly contact the substrate 110, the graphene layer 130 and the gate electrode 230, and may be formed between the gate electrode 250 and the graphene layer 130. The gate insulating layer 300 may be spaced apart from the first electrode 210 and the second electrode 230 and disposed not to contact the first electrode 210 and the second electrode 230.

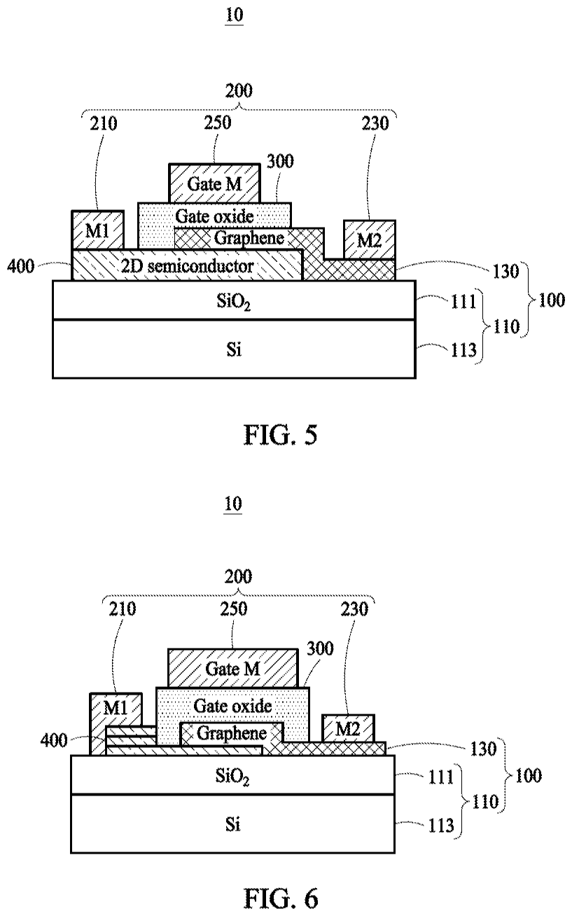

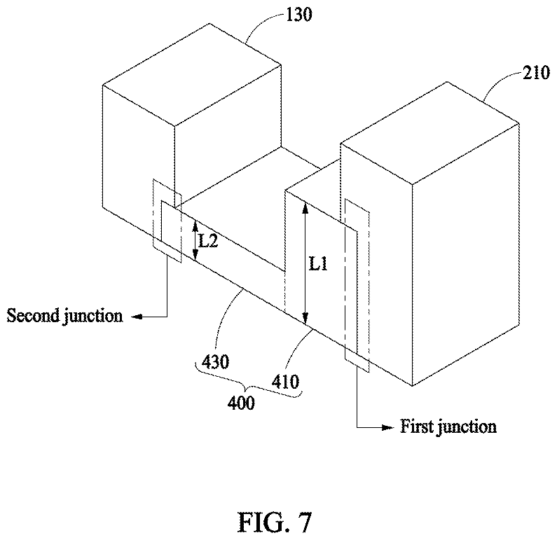

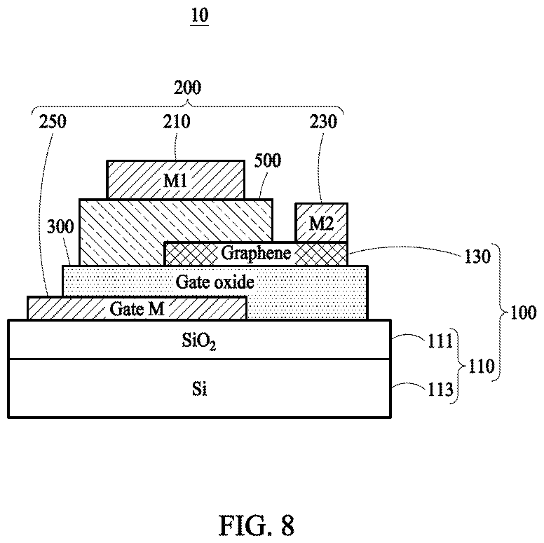

FIG. 5 illustrates another example of a barristor device-based photodetector, FIG. 6 illustrates still another example of a barristor device-based photodetector, and FIG. 7 illustrates an example of a 2D semiconductor of a photodetector shown in FIG. 6.

Referring to FIGS. 5 and 6, photodetectors 10 of FIGS. 5 and 6 have similar shapes to that of the photodetector 10 of FIG. 4. However, each of the photodetectors 10 of FIGS. 5 and 6 further includes a 2D semiconductor 400.

The substrate 110 may be implemented as a nonconductor substrate. For example, the nonconductor substrate may include at least one. SiO₂ 111 may be disposed in an upper portion of the substrate 110, and Si 113 may be disposed in a lower portion of the substrate 110.

On the substrate 110, a graphene layer 130, a plurality of electrodes 200, a gate insulating layer 300, and the 2D semiconductor 400 may be laminated. For example, the graphene layer 130 and the 2D semiconductor 400 may be laminated on the substrate 110 to be indirect contact with the substrate 110. The first electrode 210, the second electrode 230, the gate electrode 250 and the gate insulating layer 300 may be laminated without contacting the substrate 110.

The graphene layer 130 may be formed between the substrate 110 and the second electrode 230 and may extend toward the first electrode 210. For example, the graphene layer 130 may directly contact the substrate 110, the second electrode 230, the gate insulating layer 300 and the 2D semiconductor 400, and may extend from the second electrode 230 toward the first electrode 210. The graphene layer 130 may be spaced apart from the first electrode 210 and the gate electrode 250 and disposed not to contact the first electrode 210 and the gate electrode 250.

The first electrode 210 and the second electrode 230 may be laminated above the substrate 110 and spaced apart from the gate electrode 250.

For example, the first electrode 210 may be laminated on the 2D semiconductor 400 to be in direct contact with the 2D semiconductor 400. Here, the 2D semiconductor 400 may be laminated on the substrate 110 to be in direct contact with the substrate 110. The first electrode 210 may be spaced apart from the substrate 110, the graphene layer 130, the second electrode 230, the gate electrode 250 and the gate insulating layer 300, and disposed not to contact the substrate 110, the graphene layer 130, the second electrode 230, the gate electrode 250 and the gate insulating layer 300.

The second electrode 230 may be laminated on the graphene layer 130 to be in direct contact with the graphene layer 130. Here, the graphene layer 130 may be laminated on the substrate 110 to be in direct contact with the substrate 110. The second electrode 230 may be spaced apart from the substrate 110, the first electrode 210, the gate electrode 250 and the gate insulating layer 300, and disposed not to contact the substrate 110, the first electrode 210, the gate electrode 250 and the gate insulating layer 300.

The gate electrode 250 is similar to that of FIG. 4, and accordingly further description thereof is omitted.

The gate insulating layer 300 may be formed between the gate electrode 250 and the graphene layer 130. For example, the gate insulating layer 300 may directly contact the graphene layer 130, the gate electrode 230 and the 2D semiconductor 400, and may be formed between the gate electrode 250 and the graphene layer 130. The gate insulating layer 300 may be spaced apart from the substrate 110, the first electrode 210 and the second electrode 230 and disposed not to contact the substrate 110, the first electrode 210 and the second electrode 230.

The 2D semiconductor 400 may include at least one of tungsten disulfide, transition metal dichalcogenides (TMDs), and black phosphorus. For example, TMDs may include at least one of WSe₂, WTe₂, MoS₂, MoSe₂, and MoTe₂.

The 2D semiconductor 400 may be formed to contact the first electrode 210 and the graphene layer 130. For example, the 2D semiconductor 400 may be formed to directly contact the substrate 110, the graphene layer 130, the first electrode 210, and the gate insulating layer 300. The 2D semiconductor 400 may be spaced apart from the second electrode 230 and the gate electrode 250 and disposed not to contact the second electrode 230 and the gate electrode 250.

The 2D semiconductor 400 includes a first layer formed with a first thickness, and a second layer formed with a second thickness. For example, the first thickness may be one of the same thickness as the second thickness and a thickness different from the second thickness. A 2D semiconductor 400 of FIG. 7 may include a first layer 410 formed with a first thickness L1, and a second layer 430 formed with a second thickness L2. Here, the second thickness L2 may be greater than the first thickness L1. For example, the first layer 410 and the second layer 430 may be formed with different thicknesses through at least one of a semiconductor growth, a thermal etching scheme, a chemical etching scheme, and a laser etching scheme.

The first layer may form a first junction with the first electrode 210, and the second layer may form a second junction with the graphene layer 130. For example, the first junction may be one of a Schottky junction and an ohmic junction, and the second junction may be one of the Schottky junction and the ohmic junction. In FIG. 7, a first junction formed between the first layer 410 and the first electrode 210, that is, a drain electrode may be an ohmic junction. A second junction between the second layer 430 and the graphene layer 130 may be a Schottky junction.

The 2D semiconductor 400 may have a characteristic (or properties) in which an energy band gap of the 2D semiconductor 400 varies depending on a thickness of a layer. For example, the 2D semiconductor 100 may form a Schottky junction having various barrier sizes from an ohmic junction by a junction of metal. Here, a size of a Schottky barrier may be controlled based on a thickness of the 2D semiconductor 400.

Current may or may not flow in the 2D semiconductor 400 by voltage of the first electrode 210.

When a forward bias (for example, V_{D}>0) is input, the 2D semiconductor 400 may not have a barrier that hinders movement of electrons (that is, resistance may decrease). Here, current may easily flow.

When a reverse bias (for example, V_{D}<0) is input, the 2D semiconductor 400 may have a barrier that hinders the movement of the electrons. Here, the current may not easily flow.

In other words, the 2D semiconductor 400 may be formed by varying the thicknesses of the first layer 110 and the second layer 130, and thus a cost used for an additional process for a junction may be saved.

Also, the 2D semiconductor 400 may determine a size of an initially generated Schottky barrier by adjusting the thickness of the 2D semiconductor 100, and thus it is possible to implement a device performance used in various locations. The 2D semiconductor 400 may provide an additional degree of freedom in thickness in fabricating of a semiconductor device, so as to be included and fabricated in semiconductor devices with various structures.

FIG. 8 illustrates yet another example of a barristor device-based photodetector.

Referring to FIG. 8, a shape of a photodetector 10 of FIG. 8 is not similar to a shape of the photodetector 10 of FIG. 4. The photodetector 10 of FIG. 8 includes a substrate 110, a graphene layer 130, a plurality of electrodes 200, and a gate insulating layer 300. Also, the photodetector 10 of FIG. 8 further includes an insulating layer 500.

The substrate 110 is similar to that of FIG. 4, and accordingly further description thereof is omitted. However, the insulating layer 500 may be laminated without contacting the substrate 110.

The graphene layer 130 may be formed between the substrate 110 and a second electrode 230 and may extend toward a first electrode 210. For example, the graphene layer 130 may directly contact the second electrode 230, the gate insulating layer 300 and the insulating layer 500, and may be formed between the second electrode 230 and the gate insulating layer 300. Here, the gate insulating layer 300 may be laminated on the substrate 110 to be in direct contact with the substrate 110. The graphene layer 130 may be spaced apart from the substrate 110, the first electrode 210 and a gate electrode 250, and disposed not to contact the substrate 110, the first electrode 210 and the gate electrode 250.

The first electrode 210 and the second electrode 230 may be laminated above the substrate 110 and may be spaced apart from the gate electrode 250.

For example, the first electrode 210 may be laminated on the insulating layer 500 to be in direct contact with the insulating layer 500. Here, the insulating layer 500 may be laminated on the gate insulating layer 300 to be in direct contact with the gate insulating layer 300. The first electrode 210 may be spaced apart from the substrate 110, the graphene layer 130, the second electrode 230, the gate electrode 250 and the gate insulating layer 300, and disposed not to contact the substrate 110, the graphene layer 130, the second electrode 230, the gate electrode 250 and the gate insulating layer 300.

The second electrode 230 is similar to that of FIG. 4, and accordingly further description thereof is omitted. However, the second electrode 230 may be spaced apart from the insulating layer 500 and disposed not to contact the insulating layer 500.

The gate electrode 250 may be laminated on the substrate 110. For example, the gate electrode 250 may directly contact the substrate 110 and the gate insulating layer 300 and may be formed between the substrate 110 and the gate insulating layer 300. The gate electrode 250 may be spaced apart from the graphene layer 130, the plurality of electrodes 200 and the insulating layer 500 and disposed not to contact the graphene layer 130, the plurality of electrodes 200 and the insulating layer 500.

The first electrode 210, the second electrode 230 and the gate electrode 250 may be formed of the same metal (or metal layer), formed of different metals, or formed of polysilicon. For example, the first electrode 210 may be a drain electrode formed of the same metal (or metal layer) as or a different metal from the second electrode 230 and the gate electrode 250, or formed of polysilicon. The second electrode 230 may be a source electrode formed of the same metal (or metal layer) as or a different metal from the first electrode 210 and the gate electrode 250, or formed of polysilicon. The gate electrode 250 may be a gate electrode formed of the same metal (or metal layer) as or a different metal from the first electrode 210 and the second electrode 230, or formed of polysilicon. This corresponds to the first electrode 210, the second electrode 230 and the gate electrode 250 included in the photodetector 10 of FIG. 8, however, example embodiments are not limited thereto. For example, the above description may be equally applicable to the first electrode 210, the second electrode 230 and the gate electrode 250 included in the photodetectors 10 of FIGS. 4, 5 and 6.

The gate insulating layer 300 is similar to that of FIG. 4, and accordingly further description thereof is omitted. However, the gate insulating layer 300 may directly contact the insulating layer 500 and may be disposed under the insulating layer 500.

Also, the gate insulating layer 300 may be one of silicon oxide, silicon nitride, hafnium oxide, aluminum oxide, and titanium oxide. The gate insulating layer 300 may perform insulation so that the gate electrode 250 may not contact the graphene layer 130. This corresponds to the gate insulating layer 300 included in the photodetector 10 of FIG. 8, however, example embodiments are not limited thereto. For example, the above description may be equally applicable to the gate insulating layer 300 included in the photodetectors 10 of FIGS. 4.5 and 6.

The insulating layer 500 may be formed between the graphene layer 130 and the first electrode 210. For example, the insulating layer 500 may be formed to be indirect contact with the graphene layer 130, the first electrode 210 and the gate insulating layer 300. The insulating layer 500 may be spaced apart from the substrate 110, the second electrode 230 and the gate electrode 250 and disposed not to contact the substrate 110, the second electrode 230 and the gate electrode 250.

The insulating layer 500 may perform insulation so that the first electrode 210 may not contact the graphene layer 130.

The photodetector 10 implemented as shown in FIGS. 4, 5, 6 and 8 may specify and vary a wavelength band of energy of absorbed light, by adjusting a wavelength band of minimum energy of the absorbed light by changing gate voltage for the gate electrode 250. For example, the photodetector 10 may change the gate voltage for the gate electrode 250 to adjust the energy barrier E_{b} of the barristor device 100 and adjust a height of a Schottky junction of a 2D semiconductor.

The photodetector 10 may provide technology of adjusting a wavelength band of minimum energy of absorbed light to be further widened, using a 2D semiconductor having a characteristic in which an energy band gap varies depending on a thickness, and of more widely varying a wavelength band of energy of the absorbed light.

The photodetector 10 may simultaneously detect and measure an intensity and energy of light, based on the barristor device 100. For example, the photodetector 10 may be utilized in a sensor that measures various wavelength bands based on a combination of materials of the barristor device 100. The photodetector 10 may be utilized in a gas sensor by detecting and measuring energy of light and detecting a gas component. The photodetector 10 may be utilized in an image sensor by changing gate voltage and detecting energy of light. The photodetector 10 may be utilized in an image sensor that measures a visible ray region and an infrared ray (IR) region using a barristor device that measures the IR region. Here, the photodetector 10 may simultaneously measure energy of light in the IR region.

Hereinafter, an image sensor 600 including a photodetector 10 will be described with reference to FIGS. 9, 10 and 11.

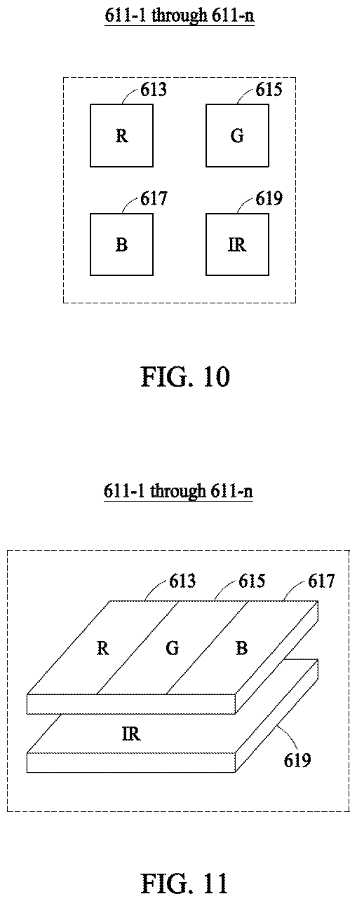

FIG. 9 illustrates an example of an image sensor including a barristor device-based photodetector, FIG. 10 illustrates an example of a plurality of pixels of FIG. 9, and FIG. 11 illustrates another example of a plurality of pixels of FIG. 9.

Referring to FIGS. 9 through 11, the image sensor 600 includes a pixel array 610, and a signal processing circuit 630. The pixel array 610 may include a plurality of pixels 611-1 through 611-n. Each of the plurality of pixels 611-1 through 611-n may include a photodetector 10.

The plurality of pixels 611-1 through 611-n may include a plurality of color pixels 613, 615 and 617, and an infrared ray (IR) pixel 619. The plurality of color pixels 613, 615 and 617 may be a red pixel 613, a green pixel 615, and a blue pixel 617, respectively.

In an example, as shown in FIG. 10, the plurality of color pixels 613, 615 and 617, and the infrared ray (IR) pixel 619 may be configured with a planar cell structure.

In another example, as shown in FIG. 11, the plurality of color pixels 613, 615 and 617, and the infrared ray (IR) pixel 619 may be configured with a tandem cell structure.

The plurality of pixels 611-1 through 611-n may include a barristor device-based photodetector 10. For example, to detect light in a visible ray band, each of the plurality of color pixels 613, 615 and 617 may include a barristor device-based photodetector 10. The IR pixel 619 may include a barristor device-based photodetector 10, to detect light in an infrared band. The IR pixel 619 may be a spectroscopic IR pixel.

The photodetector 10 is the same as the photodetectors described above with reference to FIGS. 4 through 8, and accordingly further description thereof is omitted.

The image sensor 600 may generate an image for light incident on the image sensor 600, through the pixel array 610 and the signal processing circuit 630.

For example, the pixel array 610 may output an amount of charges according to an intensity based on energy of the light incident on the image sensor 600 through the photodetector 10. The pixel array 610 may transmit a signal for at least one of a visible ray band and an infrared band corresponding to an amount of charges output through the plurality of color pixels 613, 615 and 617, and the IR pixel 619 to the signal processing circuit 630. Here, the signal may be an analog signal.

The signal processing circuit 630 may generate and transmit an image signal corresponding to at least one of the visible ray band and the infrared band through the received signal. Here, the image signal may be a digital signal.

The apparatuses described herein may be implemented using a hardware component, a software component and/or a combination thereof. For example, the apparatuses and components described in the example embodiments may be implemented using one or more general-purpose or special purpose computers, such as, for example, a processor, a controller and an arithmetic logic unit (ALU), a digital signal processor, a microcomputer, a field programmable gate army (FPGA), a programmable logic unit (PLU), a microprocessor or any other device capable of responding to and executing instructions in a defined manner. A processing device may nm an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors.

Software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The method according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

While this disclosure includes specific example embodiments, it will be apparent to one of ordinary skill in the art that various changes in form and details may be made in these example embodiments without departing from the spirit and scope of the claims and their equivalents. The example embodiments described herein are to be considered in a descriptive sense only, and not for purposes of limitation. Descriptions of features or aspects in each example embodiment are to be considered as being applicable to similar features or aspects in other example embodiments. Suitable results may be achieved if the described techniques are performed in a different order, and/or if components in a described system, architecture, device, or circuit are combined in a different manner and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

1. A photoconductor comprising:
a substrate;
a gate electrode laminated on the substrate;
a first electrode and a second electrode laminated on the substrate and spaced apart from the gate electrode;
a graphene layer formed between the substrate and the second electrode and extending toward the first electrode; and
a gate insulating layer formed between the gate electrode and the graphene layer.

2. The photoconductor of claim 1, wherein the substrate is implemented as at least one of a semiconductor substrate and a nonconductor substrate.

3. The photoconductor of claim 2, wherein the substrate is one of silicon, germanium, silicon-germanium, a Group I-V semiconductor, a Group I-VI semiconductor, a semiconducting CNT, MoS₂, IZO, and GIZO.

4. The photoconductor of claim 2, wherein the nonconductor substrate comprises at least one of SiO₂, and Si.

5. The photoconductor of claim 1, further comprising:
a two-dimensional (2D) semiconductor formed to contact the first electrode and the graphene layer.

6. The photoconductor of claim 5, wherein
the 2D semiconductor comprises:
a first layer formed with a first thickness; and
a second layer formed with a second thickness, and
the first layer forms a first junction with the first electrode and the second layer forms a second junction with the graphene layer.

7. The photoconductor of claim 6, wherein the first thickness is either the same as or different from the second thickness.

8. The photoconductor of claim 6, wherein
the first junction is one of a Schottky junction and an ohmic junction, and
the second junction is one of the Schottky junction and the ohmic junction.

9. The photoconductor of claim 5, wherein the 2D semiconductor is at least one of tungsten disulfide, transition metal dichalcogenides (TMDs), and black phosphorus.

10. The photoconductor of claim 9, wherein the TMs comprise at least one of WSe₂, WTe₂, MoS₂, MoSe₂, and MoTe₂.

11. The photoconductor of claim 1, further comprising:
an insulating layer formed between the graphene layer and the first electrode.

12. The photoconductor of claim 1, wherein the gate electrode directly contacts the substrate and is formed between the substrate and the gate insulating layer.

13. An image sensor comprising:
a pixel array comprising a plurality of color pixels and an infrared ray (IR) pixel comprising a photoconductor based on a barristor device to detect light in an IR band,
wherein the photoconductor comprises:
a substrate;
a gate electrode laminated on the substrate;
a first electrode and a second electrode laminated on the substrate and spaced apart from the gate electrode;
a graphene layer formed between the substrate and the second electrode and extending toward the first electrode; and
a gate insulating layer formed between the gate electrode and the graphene layer.

14. The image sensor of claim 13, wherein the substrate is implemented as at least one of a semiconductor substrate and a nonconductor substrate.

15. The image sensor of claim 14, wherein the substrate is one of silicon, germanium, silicon-germanium, a Group III-V semiconductor, a Group II-VI semiconductor, a semiconducting CNT, MoS₂, IZO, and GIZO.

16. The image sensor of claim 14, wherein the nonconductor substrate comprises at least one of SiO₂, and Si.

17. The image sensor of claim 13, further comprising:
a two-dimensional (2D) semiconductor formed to contact the first electrode and the graphene layer.

18. The image sensor of claim 17, wherein
the 2D semiconductor comprises:
a first layer formed with a first thickness; and
a second layer formed with a second thickness, and
the first layer forms a first junction with the first electrode and the second layer forms a second junction with the graphene layer.

19. The image sensor of claim 18, wherein the first thickness is either the same as or different from the second thickness.

20. The image sensor of claim 18, wherein
the first junction is one of a Schottky junction and an ohmic junction, and
the second junction is one of the Schottky junction and the ohmic junction.

21. The image sensor of claim 17, wherein the 2D semiconductor is at least one of tungsten disulfide, transition metal dichalcogenides (TMDs), and black phosphorus.

22. The image sensor of claim 21, wherein the TMDs comprise at least one of WSe₂, WTe₂, MoS₂, MoSe₂, and MoTe₂.

23. The image sensor of claim 13, further comprising:
an insulating layer formed between the graphene layer and the first electrode.

24. The image sensor of claim 13, wherein the gate electrode directly contacts the substrate and is formed between the substrate and the gate insulating layer.
